(19) United States
(12) Patent Application Publication
(10) Pub. No.: US 2025/0040311 A1
(43) Pub. Date: Jan. 30, 2025

(54) LED CIRCUIT BOARD AND LIGHT EMITTING MODULE

(71) Applicant: CoeLux S.r.l., Lomazzo (CO) (IT)

(72) Inventors: Paolo Di Trapani, Cavallasca (IT); Paolo Ragazzi, Gorgonzola (IT)

(21) Appl. No.: 18/713,762

(22) PCT Filed: Dec. 2, 2022
(86) PCT No.: PCT/IB2022/061698

§ 371 Date: May 28, 2024

(30) Foreign Application Priority Data
Dec. 9, 2021 (IT) 102021000030980

(51) Int. Cl. H01L 33/48; H01L 25/075; H01L 33/46; H01L 33/58; H01L 33/62; H01L 33/64

(52) U.S. Cl. CPC H01L 33/486; H01L 25/0753; H01L 33/46; H01L 33/58; H01L 33/62; H01L 33/647

(57) ABSTRACT

A circuit board for a light emitting module, comprises a plurality of mounting positions for LEDs, wherein the mounting positions are distributed in a regular two-dimensional pattern on a first surface side of the circuit board. The circuit board is characterized by (i) a plurality of transparent domains, each transparent domain extending around one mounting position of the plurality of mounting positions, and (ii) a plurality of thermally conductive domains, each thermally conductive domain being electrically and thermally connected to at least one mounting position. An average area of the electrically conductive domains is at least 2% of an average area of the transparent domains. Each thermally conductive domain of the plurality of thermally conductive domains comprises at least a portion, which extends as a two-dimensional area on a surface of the circuit board.

### TECHNICAL FIELD

The present disclosure relates generally to light emitting devices, and in particular light emitting devices based on arrayed arrangements of LEDs. Moreover, the present disclosure relates generally to modular configurations of lighting systems that can be implemented as sun-sky-lighting systems.

### BACKGROUND

Sun-sky-lighting systems are described in a plurality of patent applications by the applicant. In particular, the illumination in those systems is based on a directed light beam (representing sun-like illumination) that can be generated in various manners, whereby compact and energy efficient light sources are of interest.

Thus, the present disclosure is directed, at least in part, to improving or overcoming one or more aspects of prior systems.

### SUMMARY OF THE DISCLOSURE

In an aspect, the present disclosure is directed to a circuit board for a light emitting module. The circuit board comprises a plurality of mounting positions for LEDs, wherein the mounting positions are distributed in a regular two-dimensional pattern on a first surface side of the circuit board. The circuit board is characterized by
(i) a plurality of transparent domains, each transparent domain extending around one mounting position of the plurality of mounting positions, and
(ii) a plurality of thermally conductive domains, each thermally conductive domain being thermally and electrically connected to at least one mounting position,
wherein an average area of the thermally conductive domains is at least 2% or at least 4% or at least 8% of an average area of the transparent domains; and
wherein each thermally conductive domain of the plurality of thermally conductive domains comprises at least a portion which extends as a two-dimensional area on a surface of the circuit board.

Within the scope of the present description and the appended claims, with the expression “two-dimensional area” an area is indicated, which shows an extension in the spatial coordinates which is substantially non-predominant in a first spatial coordinate with respect to a second spatial coordinate, such as an extension in the first spatial coordinate which is less than 15 times an extension in the second spatial coordinate, preferably less than 10 times the extension in the second spatial coordinate, more preferably less than 5 times the extension in the second spatial coordinate. Alternatively, the expression “two-dimensional area” may indicate an area that has a significant size, namely a size of a surface at least 3 times, possibly 30 times, more favorably 300 times larger than the size of a light emitting surface (LES) of an LED configured to be mounted in a mounting position of the circuit board.

In another aspect, the present disclosure is directed to a circuit board for a light emitting module. The circuit board comprises a plurality of mounting positions for LEDs, wherein the mounting positions are distributed in a regular two-dimensional pattern on a first surface side of the circuit board. The circuit board is characterized by
(i) a plurality of transparent domains, each transparent domain extending around one mounting position of the plurality of mounting positions, and
(ii) a plurality of electrically conductive domains, each electrically conductive domain being electrically connected to a couple of mounting positions,
wherein an average area of the electrically conductive domains is at least 2% or at least 4% or at least 8% of an average area of the transparent domains; and
wherein each electrically conductive domain of the plurality of electrically conductive domains comprises at least a portion which extends as a two-dimensional area on the first surface side of the circuit board.

In another aspect, the present disclosure is directed to a light emitting module that comprises a reflector panel having an inner surface side subdivided into a two-dimensional array of surface sections, such as surface sections having a square or hexagonal geometry, generally a geometry that allows combination to cover a continuous surface, wherein each surface section comprises a concave reflecting surface area and a thermal contact area outside of the concave reflecting surface area. The light emitting module comprises further a transparent circuit board mounted to the reflector panel with a first surface side facing the inner surface side of the reflector panel, and LEDs distributed in a two-dimensional array on the first surface side of transparent circuit board such that each LED is associated with one of the concave reflecting surface areas. Furthermore, the light emitting module comprises heat conductors that respectively thermally connect one of the LEDs with one of the thermal contact areas. In particular, during operation of the light emitting module, light emitted from one of the LEDs is reflected by one of the concave reflecting surface areas to pass through the transparent circuit board, and heat generated by the LEDs is spread via the heat conductors and the thermal contact areas, e.g. by transmitting it to the reflector panel. Alternatively, in case the light emitting module comprises a dedicated heat sink, the heat generated by the LEDs is transmitted to the heat sink via the heat conductors and the thermal contact areas.

In a second aspect, the present disclosure is directed to a light emitting module that comprises a reflector panel having an inner surface side subdivided into a two-dimensional array of surface sections, such as surface sections having a square or hexagonal geometry, generally a geometry that allows combination to cover a continuous surface, wherein each surface section comprises a concave reflecting surface area. The light emitting module comprises further a transparent circuit board mounted to the reflector panel with a first surface side facing the inner surface side of the reflector panel, and LEDs distributed in a two-dimensional array on the first surface side of transparent circuit board such that each LED is associated with one of the concave reflecting surface areas. Furthermore, the light emitting module comprises a lens arrangement mounted at a distance of at least 3 times of a maximum extension in one direction, such as a side length of a square surface section, from the transparent circuit board (in particular to limit chromatic effects by refraction as the collimation is primarily performed by reflection as also discussed below) and comprising a plurality of abutting lenses respectively associated with one of the surface sections. In particular, during operation of the light emitting module, light emitted from one of the LEDs is reflected by the associated one of the concave reflecting surface areas to pass through the transparent circuit board, and collimated by one of the lenses of the lens arrangement.

In another aspect, a light emitting module comprises an in particular rectangular (such as square) reflector panel comprising a 2D regular array of concave mirrors, an in particular rectangular (such as square) transparent circuit board comprising at least partially transparent regions, and a 2D regular array of LEDs disposed on the transparent circuit board based on an in particular square basic array cell and arranged to illuminate the reflector panel and associated with the 2D regular array of concave mirrors, wherein each concave mirror is configured to reflect at least part of the light emitted from one of the LEDs to pass through the at least partially transparent regions. The reflector panel is thermally connected to the transparent circuit board at regions through which reflected light does not pass.

In another aspect, a circuit board for a light emitting module comprises a (n electrically insulating) (e.g. transparent) support board, a plurality of LEDs distributed in a regular two-dimensional pattern on a first surface side of the support board, wherein each LED has a heat sink that is positioned at a center of a first surface domain of the support board, the first surface domains defining light transmitting regions of the support board that extend around the LEDs, and a thermal circuit structure. The thermal circuit structure comprises a thermally conductive layer formed on the first surface side at a plurality of second surface domains of the support board, and thermal connections respectively connecting one of the heat sinks with the thermally conductive layer in one of the second surface domains. The circuit board further comprises an electrical circuit structure comprising a plurality of electrical connections formed on the first surface side of the support board for supplying power to the plurality of LEDs.

In another aspect, a circuit board for a light emitting module comprises a (n electrically insulating) support board, a plurality of LEDs distributed in a regular two-dimensional pattern on a first surface side of the support board, wherein each LED is positioned in a central area of a first surface domain of the support board, the first surface domains defining light transmitting regions of the support board that extend around the LEDs, and an electrical circuit structure for supplying power to the plurality of LED. The electrical circuit structure comprises, on the first surface side of the support board, a plurality of areal electrical connecting sections at second surface domains of the support board, which are formed between the first surface domains and define heat removing regions of the support board that extend outside the light transmitting regions, and a plurality of linear electrical connecting sections extending across the first surface domains to electrically and thermally connect the LEDs with the areal electrical connecting sections.

In another aspect, the linear electrical connecting sections have a first thickness in a dimension orthogonal to the surface of the circuit board and the areal electrical connecting sections have a second thickness in a dimension orthogonal to the surface of the circuit board, with the first thickness being larger than the second thickness, such as 1.5 times larger, 2 times larger or 4 times larger.

In another aspect, an LED-based optical system/light emitting module comprises a support board with a plurality of mounting positions. The mounting positions are distributed in a regular two-dimensional pattern on a first surface side of the support board, and the support board is transparent with respect to visible light at least within a plurality of transmission areas (light transmitting regions), each transmission area extending around one of the plurality of mounting positions. The regular two-dimensional pattern is defined by equal distances between neighboring mounting positions in a respective direction, such as in two directions, in particular in two orthogonal directions. The light emitting module comprises further a plurality of light sources mounted to the support board at the plurality of mounting positions, wherein each light source includes at least one LED, and a reflector panel having a three-dimensionally shaped surface and mounted to the support board. The three-dimensionally shaped surface faces the first surface side of the support board and includes a plurality of connecting surface sections (thermal contact areas) and a plurality of reflective surface sections (concave reflecting surface areas), the plurality of connecting surface sections extends within a connecting plane and is in contact with the first surface side of the support board, and each reflective surface section faces an associated transmission area of the support board; and a plurality of conducting tracks (heat conductors) extending on the first surface side and configured for thermal dissipation of heat from the light source and/or for power supply of the light source, wherein at least one of the plurality of conducting tracks extends from one of the plurality of mounting positions to at least one of the plurality of connecting surface sections.

### Optical Cell

Functionally, an LED and the associated surface section, specifically the concave reflecting surface area, can be considered to form an optical cell. In the optical cell, the LED is positioned in/close to a focus region of the concave reflecting surface area and is configured to emit light onto the concave reflecting surface area. The concave reflecting surface area is configured to reflect the light to pass through a transmission area of transparent circuit board.

A plurality of optical cells can be considered as a pre-collimated LED integrated unit/system suitable in particular for illumination applications requiring a directed light beam.

### Base Shape

Generally, the light emitting module can have a base shape that is defined by an array/arrangement of optical cells, each optical cell comprising an LED and an associated “surface” section. Generally, a geometry may be selected that allows a combination of the “surface” sections to cover a continuous surface. An example for a base shape is a rectangular base shape generated by a plurality of optical cells associated with a square surface section. Another base shape can be derived from a, for example, optical cell associated with a hexagonal surface section combined in a honeycomb-like structure.

As will be understood, the various concepts and advantages may apply to different shapes of the surface sections. For simplicity, however, most of the drawings explain the concepts based on an illustrated square shape, which should not to be understood as limiting the range of implementable geometries unless specific features of a square shape are advantageous. For example, a square shape of the surface sections maybe of advantage with respect to implementing the herein disclosed modularity concept as it enables a simple tile-like assembly of desired shapes.

In some embodiments, the shape of the light emitting module is defined by the number and size of the, e.g., square or hexagonal, surface sections of the reflector panel. An exemplary rectangular base shape may comprise m=3 rows of square optical cells with each row comprising, for example, n=3 cells, resulting in a square base shape of the light emitting module. Alternative numbers of rows and/or cells per row may be in the range from 3 to 20 such as 5 or 10.

Exemplary dimensions of the light emitting module including the secondary collimation by a lens array are, for example, a square base of 100 mm×100 mm and a height of about 60 mm or a square base of 30 mm×30 mm and a height of about 60 mm.

In some embodiments, large numbers of optical cells can be combined to form the complete output aperture of a lighting system as there may be configurations that do not require the modularity concept disclosed herein, e.g., due to specific choices of materials or efficient thermal management. It will be acknowledged that the modular concepts disclosed herein may, however, simplify the thermal management.

### Size for Sun-Sky-Imitating Lighting Systems

In particular for the use of the light emitting modules in sun-sky-imitating lighting systems, the maximum extension of a square surface section, such as a side length of a square surface section, and, thus, a lateral extension of an optical cell can be, for example, in the range from 1 mm to 50 mm, e.g., in the range from 3 mm to 20 mm such as 10 mm. Generally, the size is given by the available light output of the LED which needs to provide a sufficient flux for the associated output area corresponding to a respective portion of the imitated sky.

### Primary Collimation Layer/Reflector Panel

A reflector panel can have an inner surface side subdivided into a two-dimensional array of surface sections. Each surface section comprises a concave reflecting surface area and a thermal contact area outside of the concave reflecting surface area. A concave reflecting surface area may be configured as a rotational paraboloid with a focus at an LED position for orthogonal light emission. A displacement of an LED with respect to the focus position can be used, in particular, for tilting an output light beam into discrete angles given by structural considerations described herein.

In some embodiments, the concave reflecting surface area may be configured as a facetted reflector. Thereby, rearrangement of light rays contributing at specific positions within the secondary collimation layer may be controlled, allowing intra-channel homogenization. The facetted reflector may comprise a plurality of substantially planar (or curved) mini reflective facets wherein each mini reflective facet has an area substantially smaller than an area of the concave reflecting surface area, e.g., 100 times, 1000 times, 10000 times smaller. In particular in context with miniLEDs, the dimensions of the concave reflecting surface areas allows for faceted structures.

In particular for sky imitating illumination, a fully flashed plane with a uniform flux/luminance may be desired. For example, a homogeneous sky can be achieved using a flattop profile that can be created with such a facetted reflector constituting the concave reflecting surface area.

The reflector panel may be a metal plate having the required three-dimensional surface shape. It will be understood that an electrical insulation (e.g., a dielectric layer) may be required between the reflector panel and the thermal contact areas if the thermal contact areas are used for supplying power to the LEDs. An insulating layer may be provided at the circuit board and/or the reflector panel.

Alternatively, the reflector panel may be a moulded plastic panel having a metallic coating (such as an Aluminum coating or (e.g., SiO2 coated) protected Aluminum coating) covering at least the concave reflecting surface areas for providing the required reflectivity (e.g., generated by localized metal depositions).

At the position of the thermal contact areas, the thickness of the panel is increased (e.g., 1cm) such that specifically provided metal inserts may increase the heat transfer from the circuit board to the backside of the reflector panel or the ambient. As for a metallic reflector panel, an insulating layer may be part of the circuit board (e.g., applied locally or over the complete first surface side). In addition or alternatively, an insulating layer may form the thermal contact area of the metal inserts.

In some embodiments, the metal inserts may be configured as an array of pins for positioning and fixing the reflector panel (or several reflector panels) onto a metal frame. The metal frame can, thus, ensure a rigid mounting of the light emitting module(s). In addition or alternatively, the frame may function as a heat dissipator transferring the heat received from the LEDs towards the external ambient. The backside of the frame may have a grid metal structure, e.g., an Aluminum grid.

### Heat Conductors

Generally, heat conductors can include heat conducting tracks that extend on the first surface side and are configured for supporting dissipation of heat from the LEDs. The heat conducting tracks may additionally be used for power supply of the LEDs. Generally, at least one of the heat conducting tracks may extend from an LED to at least one of the plurality of connecting surface sections.

The herein disclosed heat management addresses the situation, where the heat generated by the LED during operation is to be transported across a light transmitting area of the support board. Clearly, any blocking of transmitted light is to be reduced to an acceptable amount. The support board within the circuit board may be made of, e.g., glass, Sapphire, PET or a transparent polymer, such as PMMA, Polycarbonate. The support board is essentially electrically and thermally non-conductive. Therefore, the circuit board can comprise one or more heat conductors that are provided on the support board. A heat conductor may extend on the surface of the transparent board from the LED's mounting position to an area outside of the light transmitting area. The projected width of a heat conductor (here the thickness of the heat conductor projected onto the plane of the support board) determines the area that blocks any light (in particular the light back reflected from the concave reflecting surface area) from passing through the light transmitting area. It will be understood that that area is to be kept small. Depending on the provided current to be sent through the heat conductor, its length, and the required cross-section for transferring the heat, the projected width may be, e.g., 0.5 mm or less such as a few hundred micrometers. As said the light transmitting area can be blocked by light absorbing structures applied to the support board such as any heat conductor, any electrical conductor, or the LED/LED mount. The percentage of any light blocking area with respect to the size of the light beam passing through the circuit board, usually called light transmitting area, is preferably below 15% such as below 10%. Blocking areas of 2% or 5% may be possible depending on the overall configuration of the LED circuitry.

Starting point of the heat conductor can be, for example, a heat sink of the LED or an electrical lead providing power to the LED. Preferably, the shortest path from the LED to the outside can be used, e.g., radial course of the heat conductor.

As the light blocking cross-section is a parameter determining the transmission, as explained below, heat conductors may extend, e.g., orthogonally to the board to provide a sufficient cross-section for the heat flow, but maintain a small projected width.

Alternative electrical and/or thermal connections can be based on an ITO-layer. The ITO-layer can be applied to essentially cover the complete first surface side of the support board, such as 95% of the first surface side or 92% of the first surface side, or function as a localized conductive connector. It is noted that a complete covering of the light transmitting area may result in (light transmission) losses in the range from 20% to 10% or less, in particular if only a limited area is covered by the ITO-layer.

### Primary Light Source Panel/PCB with LEDs

In some embodiments, the transparent circuit board can be a printed circuit board (PCB) that is based on a support board. Generally, the support board can be made of a transparent material that is transparent with respect to the LED light, generally visible light (such as glass, Sapphire, PET or a transparent polymer, such as PMMA, Polycarbonate) having transparencies in the range from, for example, 75% and more, such as 85% and more or 95% and more, preferably even a transparency larger than 98% for glass or Sapphire (without any light blocking structure on the surface). On the support board, electrical connections for electrically connecting to the leads of the LEDs can be printed, thereby defining specific LED mounting positions. The LED mounting positions can be arranged equally spaced as a first 2D, e.g., square/hexagonal, array (“1st matrix”). The LED mounting positions may be implemented as LED-holders providing electrical contact of easily mountable LEDs to the electrical connections. Alternatively, soldering contacts may be provided to connect an LED with its electrical connections. The electrical connections (leads) of the LEDs can also function as heat conductors.

### LEDs

The LEDs may have a lateral dimension of the light emitting area in the range of several 100 micrometers, for example, between 100 micrometers and 800 micrometers, or between 200 micrometers and 600 micrometers, such as 400 micrometers (often referred to as miniLEDs, in contrast to microLEDs or conventional large-scale LEDs).

With respect to homogeneous light output, substantially identical (mini) LEDs can be used within substantially identical optical cells, e.g., substantially identical geometry/shape of the concave reflecting surface areas and lenses.

The LEDs of the pre-collimated LED integrated units are disposed onto the transparent circuit board with a pitch D significantly larger than the “averaged” size d of, e.g., a miniLED such as 5×, 10×, 15×, preferably 20× larger. With respect to the distance between the 1^{st} and 2 ^{nd} collimation layers, the pitch between LED mounting positions may be 3 times or 4 times smaller than that distance. For example, the pitch may be between 3 mm and 15 mm such as 10 mm.

It is noted that a pitch in the identified range can allow proper alignment of the optical system within the predefined tolerances of.

When starting from a required output light with, for example, 10,000 lm to 25,000 lm per square meter for a sun-sky-illumination, with an efficacy of 30%, this results in the need of 300 lm to 800 lm for a light emitting module of side length 10 cm and including hundred optical cells, the required output light for an optical cell is 3 lm to 8 lm that can be provided with a miniLED (emitting area of, e.g., 0.4 mm×0.4 mm) supplied with, for example, 0.1 W and an efficacy of 50-100 lm/W at a standard operating temperature. Accordingly, significant amounts of heat have to be removed from very small areas (the LEDs) even at the high LED efficacy of, e.g., 90%, and generally from the large sizes of skylights. Additionally, heating of the components by absorption of significant amounts of light will be needed to be taken into account. To ensure the operating temperature and long-term operation of the miniLEDs, approaches for heat management is proposed herein. The heat management proposed herein considers thermal resistance of heat conductors (given, for example, by cross-section and length of a wire), effects on the uniformity of the output of light (affected by losses due to the presence of the wiring), thermal expansions etc.

It is noted that having a lateral dimension of the light emitting area in the range of several 100 micrometers, in combination with optical layers having a pitch significantly larger such as 10 mm, enable beam divergences (FWHM) in the range from 3° to 20° such as 10°. Thereby, the desired optical setup can generate a uniform illuminance at distances, the nearest, in the range between 100 mm and 200 mm. Such a combination of parameters (distance and divergence) is noted to be favorable for sun-sky-lighting system but may not be intended for uniform backlighting of screens as those typically require much thinner system.

The inventors further realized in this context that LEDs with a larger light emitting area may imply a larger pitch between the LEDs and/or a larger distance to reach such a uniform illuminance. On the other side, LEDs with a smaller light emitting area may require a higher precision during assembly and operation, thus, involving more costly technologies. In addition, the overall efficacy may decrease, thereby increasing the power consumption and making heat dissipation more challenging. Based on the considerations explained herein, the range in the size of the light emitting area for configurations that are suitable-in particular for sun-sky-lighting system-can be optimized with respect to the geometrical, power, and cost parameters.

### Thermal Expansion Considerations

Limitations to the thermal expansion of the components of the light emitting module may arise. For example, in some embodiments a linear thermal expansion coefficient of the transparent circuit board and a linear thermal expansion coefficient of the reflector panel may differ by less than a factor of 10 (preferably by less than a factor of 5 or even less than a factor of 2, such as a factor of 1.5) in order to ensure, for example, optical alignment. It will be acknowledged that assuming an intended position of the LED at the position of the focus of the concave reflecting surface area, the shift in position of the LED with respect to the focus position can affect the light passage of the optical cell. The shift may cause a tilt in the output direction, partial passing through a non-associated light transmitting area and/or non-associated lens of the secondary collimation layer, which may affect the uniformity of the output light beam.

In some embodiments, the product between (i) the difference between the thermal linear expansion coefficients of the transparent circuit board and of the reflector panel, and (ii) the linear dimension of the light emitting module, which determines the difference in the thermal expansion of the board and of the reflector, can be set smaller than a dimension of the light emitting area of the LED in one direction. For example, the product may preferably be smaller than ½, more preferably than ⅓, more preferably smaller than ⅕, or even in the range of 1/10 for a temperature variation of 20° C., more preferentially 30° C., most preferably 50° C.

For example, in case of an Aluminum reflector of linear thermal expansion coefficient alpha=22 (μm/m/C) and of an acrylic support board of linear thermal expansion coefficient alpha=70 (μm/m/C) the linear dimension of the module should be less than 100 mm to ensure a relative displacement of less than 1/3 of a LED light emitting area for a 0.4 mm×0.4 mm LED light emitting area, for a temperature variation of 30° C.

In another example, for a sapphire support board (thermal expansion coefficient alpha=5) modules as large as 300 mm can be accepted for the same LED. Of course, smaller modules may be necessary in case of higher thermal variations, e.g., a respective 60 mm and 180 mm wide acrylic or sapphire support board, mounted on top of an Aluminum reflector panel, for a 50° C. temperature variation.

In some embodiments, the product between (i) the thermal linear expansion coefficients of secondary collimation layer and (ii) the linear dimension of the light emitting module, which determines the thermal expansion of the collimation layer, can be kept small to avoid stress damage. For a temperature variation of the secondary collimation layer of 20° C., more preferentially of 30° C., most preferably of 50 C.°, the product can, for example, be selected to be smaller than 10%, preferably smaller than 5%, more preferably smaller than 2%, such as about 1% of the optical cell (linear) dimension.

In case of an acrylic secondary collimation layer, for example, ensuring a thermal expansion smaller than 5% of the optical cell's linear dimension being a side length of 10 mm (e.g., an expansion smaller than 0.5 mm) may limit the size of the light emitting module to 240 mm in case of a target specification accepting 30° C. thermal variation. Assuming a maximum thermal expansion of only 2% of the optical cell's linear dimension in order to ensure optimal uniformity in the luminance/illuminance profile across abutting modules, the size of the light emitting module may be limited to 100 mm.

### Heat Dissipators

In addition to the (first) 2D, e.g., square/hexagonal, array (“1^{st} matrix”) of equally spaced LED mounting positions (e.g., LED-holders), the transparent circuit board may also comprise a second 2D, e.g., square/hexagonal, array (“2^{nd} matrix”) of equally spaced heat dissipators located at the positions of the thermal contact areas. The second 2D array may be identical to the 2D array of equally spaced LED mounting positions but displaced either laterally or diagonally with respect to the 2D array of equally spaced LED mounting positions, so that there is always one heat dissipator between each two neighbouring LEDs along, for example, a row or a diagonal line, respectively. Each LED mounting position (e.g., LED-holders) can be thermally connected (e.g., by a metallic wire) to at least one heat dissipator.

The heat dissipator may be positioned in a location where the local light flux is minimum or null. Therefore, it can have a significant size, namely a size of a surface at least 3 times, possibly 30 times, more favorably 300 times larger than the size of an LED (or with respect to the optical cell, larger than 5%, 10%, 20% of the projected area of the optical cell), thereby facilitating efficient heat transfer to the reflecting panel. It is noted that the configuration wherein the second array is diagonally displaced allows larger heat dissipators, because these can be located at larger distances from the LEDs than for the case when the second array is laterally displaced.

There are various options for transferring the heat from the heat dissipator to the reflecting panel:

In one exemplary configuration, particularly suited for the above-mentioned diagonal displacement, the heat dissipators are positioned in contact to the reflecting panel at the thermal contact areas, which may specifically be a corner or side of the surface of the surface section. In order to efficiently transfer the heat to an ultimate thermal dissipator (e.g., a flat bottom side of the reflecting panel), at least the heat transmitting “channel” of the dissipator should most likely be metallic. Accordingly, electrical connection between the heat transmitting “channel” /the reflecting panel and the electric circuit for supplying power to the LEDs is to be prevented. For example, the heat dissipator may cover the thermal contact area, and, be made if an appropriate, electrically insulating, thermal pad, e.g., a thin layer of aluminum nitride or other high thermal and low electric conductive material. Notably, given the need of cutting at some point an electric connection between the electric circuit and the heat transmitting “channel”, a place where this can be done is at the thermal contact area, allowing larger surfaces with respect to other connecting points (e.g., at the LED location).

Another exemplary configuration, particularly suited for the lateral displacement case, has the thermal contact at some distance from the reflecting panel. For example, the entire volume between the circuit board and the reflecting panel may be filled with a transparent filler, that also serves to minimize losses due to Fresnel reflection at the interface. Said filler will also fill the gap between the heat dissipator and the reflecting panel. Even if the filler may not be a highly thermally conductive material, its thickness can be made small enough and the surface of the dissipator can be made large enough to ensure adequate heat transfer to the reflector.

In another exemplary configuration, suited for the diagonal displacement case, the wiring of the LED is linear, but each point of the wire between two LED is still thermally connected to a heat dissipator.

In all exemplary configurations, the LEDs can be wired in series from on (positive) to the opposite (negative) side of the light emitting module, to enable each side to be kept at a fixed electric potential as well as series connections among groups of LEDs, this ensuring a more uniform light extraction.

### Electrical Connections

An electrical connection can provide a series connection between lines/groups of LEDs extending from one side of the transparent circuit board to an opposite side of the transparent circuit board. In the case where the second array is laterally displaced, this can be achieved by a linear connection, connecting LEDs of neighboring optical cells via a central portion along a lateral side of the optical cell. In the case where the second array is diagonally displaced, an electrical connection can follow a zig-zag course, connecting LEDs of neighboring optical cells via a corner of the optical cell.

It is noted that a group of serially connected LEDs may contain also a plurality of rows or lines, to increase the total number of LEDs per group, thereby improving the uniformity of light extraction among different groups.

### Separate Heat Dissipating Tracks

In addition or alternatively, the transparent circuit board may be provided with specific heat dissipating tracks. Such heat dissipating tracks may be printed as well but may be electrically insulated from the power providing electrical tracks.

### Pillar-Like Structures

Generally, the transparent circuit board can be supported by the thermal contact areas. In addition, the light emitting module may include pillar-like structures, for example, at four corners in case of a rectangular base shape, in particular when a secondary collimation layer (see below) needs to be mounted. Preferably, the pillar-like structures extend in regions outside of the incident and reflected light. At the level of the PCB, for example, a pillar-like structure may be associated with a dimension of its (e.g., triangular) cross-section in the range of a few millimeters such as 3 mm. Following the broadening of the emitted light beam, the pillar-like structures may narrow in cross-section, e.g., taper down to a respective dimension of, for example, 1 mm at the level of the secondary collimation layer.

### Secondary Collimation Layer/Lens Panel

A secondary collimation layer can be structurally linked/rigidly connected to the primary collimation layer to ensure a consistent and desired optical alignment. For example, in addition to carrying the transparent circuit board, the pillar-like structures may further carry an output lens arrangement (lens array/lens panel) that includes, for example, one lens on top of/associated with each optical cell. To achieve a fully flashed output aperture of the light emitting module, the lenses are of a, e.g., square/hexagonal, shape with a side length of the optical cell and abut against each other. Furthermore, lens panels of abutting light emitting modules can be configured to ensure a fully flashed extended output aperture of a plurality of light emitting module.

It is noted that preferably the lenses are mechanically attached with high precision and form a kind of a “mono-block”, i.e., the light emitting module can be configured as a rigid unit with a preset/fixed optical alignment.

It is noted that output light of the light emitting modules should be chromatically, if at all, weakly affected. Therefore, the primary collimation of the light emitted from an LED is achieved by the associated reflecting surface area. Only some final collimation is achieved through the associated lens. In consequence, the lens is positioned at a distance of at least three times the length of the optical cell, such as 5 or 8 times, and less than 10 or 20 times. In such a configuration, the diameter of a, for example, circular reflecting surface area can be smaller than the length of the optical cell. Accordingly, the pillar-like structures may be tapered, i.e., decrease in cross-section with the distance to the reflector panel.

For an orthogonal output light beam, an output lens may receive and collimate light reflected from a concave reflecting surface area located orthogonally below the lens.

Assuming that additional pillar-like structures are introduced within the cross-section of the light emitting module, it is noted that openings within the transparent circuit board may be needed.

Furthermore, if a plurality of light emitting modules is assembled in combination, pillar-like structures may be shared between neighboring light emitting modules. For square/rectangular-shaped light emitting modules, up to 4 light emitting modules may share pillar-like structures or pillar-like structures composed of up to 4 light emitting modules may be fixedly mounted together. Thus, while for a single light emitting module a pillar-like structure may be triangular in cross-section, such a commonly shared or composed pillar-like structure of four light emitting modules may be square in cross-section.

In particular referring to configurations using miniLEDs, the optical configurations disclosed herein can be based on a 3-level collimation concepts including a) the concave-shaped of the reflecting surface areas, b) the concept of facets implemented on the reflecting surface areas, and c) the secondary collimation layer. While the first two levels are insensitive with respect to the chromaticity of light, the secondary collimation layer only contributes only weakly to the final collimation within any specific allowable chromaticity distortions. Thus, the system is essentially free of chromatic aberrations.

### Tilt

Alternatively for inclined output beams, concave reflecting surface areas may reflect the light of an LED not orthogonally but instead under an inclination angle such that the reflected light is received and collimated from a single lens associated to, for example, a neighboring optical cell or even to an optical cell further away. In this way, the inclination of the output beams may be structurally limited to a discrete set of angles that depends on the size of optical cells.

It is noted that based on that concept also a plurality of output beams differently inclined can be generated.

### Lighting System

In another aspect, a lighting system is disclosed that is based on an arrangement of a plurality of light emitting modules that are positioned next to each other in a row or a two-dimensional array or any shape that can be formed by the modules. The size of the light emitting module is thereby selected such that thermal influences such as deformations do not affect the alignment of optically active elements (LEDs, concave reflecting surface areas, lenses) beyond the allowed tolerances. Accordingly, neighboring light emitting modules may-at least in the area of the transparent circuit board and the reflector-be mounted at some interspace; for this, the outer optical cells may be slight reduced in size at any connecting side, thereby resulting a “tapered” light emitting module that allows larger thermal fluctuations in the area of the heat source “LED”.

To ensure proper mounting, the lighting system may include a frame for correctly positioning and mounting the light emitting modules at respective distances.

With respect to a inclined output beam, the arrangement of light emitting modules may be such that light emitted from one of the light emitting modules passes through the secondary collimation layer of another one of the light emitting modules.

In addition, a fly's eye homogenizer based on two regular micro-lens arrays in tandem configuration, i.e., lens array with many lenslet-pairs per optical cell, may be used to homogenize the light output.

In some embodiments, the optical cell has a substantially polygonal section, where, for example, an at least one thermal contact area is located at a vertex of said polygonal section.

In some embodiments, the concave reflecting surface area substantially matches the shape of a rotational paraboloid associated with a focus at the position of the associated LED.

In some embodiments, the transparent circuit board is configured to transfer heat produced by the LED to at least one thermal contact area.

In some embodiments, the transparent circuit board is configured to establish an electric connection between an external power supply circuit at a first electric potential to a first lead of an LED and at a second electric potential to a second lead of an LED.

In some embodiments, the electrical connections are implemented as tracks or wires that transfer also heat to the associated thermal contact area which is electrically insulated from the electrical connection.

In some embodiments, the electrical connections are made of a light-transparent material.

In some embodiments, the electrical connections are made of a transparent film.

In some embodiments of the circuit board, an average area of the second surface domains associated with one LED is at least 2% such as at least 4% or at least 8% of an average area of the first surface domains associated with one LED.

In some embodiments of the circuit board, a plurality of LEDs is mounted respectively to the support board at the plurality of mounting positions.

In some embodiments of the circuit board, the electrically conductive domains have an electrical resistivity in Ω·m that is 10¹⁰, preferably 10¹⁵, even more preferably 10¹⁸ times smaller than an electrical resistivity of the transparent domains, and/or the transparent domains have a transparency that is at least 10 times larger than the transparency of the electrically conductive domains.

In some embodiments, the circuit board further comprises thin opaque electric connectors that extend across the transparent domains, and optionally are configured as a substantially flat connector that is oriented with its larger surface inclined, in particular orthogonal, to the first surface side of the support board.

In some embodiments of the circuit board, the electrically conductive domains are at least partially covered by an insulating layer. In some embodiments of the circuit board, the electrically conductive domains are made by a single material or by two different materials. In some embodiments of the circuit board, the electrically conductive domains cover at least 90% of an area of the support board that is not associated with the transparent domains.

Other features and aspects of this disclosure will be apparent from the following description and the accompanying drawings.

### BRIEF DESCRIPTION OF THE DRAWINGS

The accompanying drawings, which are incorporated herein and constitute a part of the specification, illustrate exemplary embodiments of the disclosure and, together with the description, serve to explain the principles of the disclosure. In the drawings:

FIGS. 1A-3D are schematic illustrations of exemplary light emitting modules and their components;

FIGS. 4A-6B are schematic illustrations of exemplary circuit board configurations;

FIGS. 7A and 7B are schematic illustrations of LED couplings to thermal contacts;

FIGS. 8A and 9B are schematic illustrations of exemplary circuit board configurations;

FIGS. 9C and 9D are schematic illustrations of a reflector panel and a respective light emitting module;

FIGS. 10A and 12B are schematic illustrations of exemplary circuit board configurations;

FIGS. 13A-13C and 14 are schematic illustrations of exemplary arrangements and configurations of light-emitting modules; and

FIG. 15 is schematic illustrations of another circuit board configurations.

### DETAILED DESCRIPTION

The following is a detailed description of exemplary embodiments of the present disclosure. The exemplary embodiments described therein and illustrated in the drawings are intended to teach the principles of the present disclosure, enabling those of ordinary skill in the art to implement and use the present disclosure in many different environments and for many different applications. Therefore, the exemplary embodiments are not intended to be, and should not be considered as, a limiting description of the scope of patent protection. Rather, the scope of patent protection shall be defined by the appended claims.

The disclosure is based in part on the realization that a modular concept based on light emitting modules can achieve the possibility of allowing different shapes of lighting systems (square, rectangular, with different sizes and elongations, L or T shapes, honeycomb-structure etc.). In addition, it was recognized that a modular concept can also achieve a desired precision in mutual alignment among each LED channel despite temperature variations. It was realized that limiting the size of light emitting modules may allow small enough interspaces at boundaries that then will not be not noticed, in particular in sun-sky-illuminating systems intending to imitate a continuous sky appearance. Furthermore, it was realized that a modular concept can also achieve a desired tolerance in the spatial separation among abutting light emitting modules, and specifically among the secondary collimation layer of the abutting light emitting modules. The tolerance may be set to prevent visible gaps in the produced luminance/illuminance profile, e.g., at the level of a fully flashed plane. (A fully flashed plane with a uniform flux/luminance may be usable, for example, for generating a uniform sky appearance based on Rayleigh-scattering.)

As a consequence of the modular concept, it was further realized with respect to the precision that all optical layers, such as the reflector, the transparent circuit board with the LEDs, and the collimator layer(s), preferably are rigidly connected in one single module. Using essentially identical modules additionally may allow positioning abutting identical modules in a seamless configuration.

The disclosure is further based in part on the realization that heat management in LED-based devices may be needed for long-term operation. Heat management is, in particular, to be implemented in configurations using transparent carrier boards such as transparent circuit boards or PCBs, often being reduced in heat conductivity. This aspect may also affect configurations that require maintaining optical alignment at a high level. Thus, the aspect of heat management may be considered in combination and separately with respect to the modular concept for those configurations combining reflector panels and transparent circuit boards.

Specifically, it was realized that electric and/or thermal connections to the reflector panel can be used to dissipate heat from the LEDs. In combination with the importance of uniformity for sky imitating lighting system, which imposes to make an optical cell as equal as possible in appearance to the neighboring cell in the same module (or even in the entire lighting system if consisting of a single large “module”), it was realized that the heat can preferably flow “vertically” within the module, i.e., from each LED to each “base portion” of the reflector panel and then essentially dissipate at the side of the reflector panel opposite to the reflecting surface areas. In contrast, the electrical current can flow horizontally, i.e., within the plane of the transparent circuit board, to power, for example, a line of LEDs in a series connection. For the heat dissipation concept, the inventors identified several considerations and aspects regarding the geometry:
(i) The transparent circuit board may not effectively conduct heat; thus, heat conductors (limited areas of heat conducting material) can be selectively provided within the area of the circuit board subject to light transmission, in particular if non-transparent heat wiring is used.
(ii) The reflected light may not pass through all areas of the circuit board. If larger surface areas are involved to transfer the heat, these areas should be displaced apart (be distanced) from the LED, preferably outside that area of the circuit board that is subject to light transmission.
(iii) Materials used and layouts of the circuitry should be configured to reduce the danger of any electric short-cut, e.g., between LEDs at different potentials.
(iv) To ensure the same/similar operating conditions for all LEDs, e.g., a closest possible common current, the LEDs should be connected in series and, for example, divided in groups of the same number of LEDs. For example, each group of LEDs should be arranged in a row. It is noted that an odd number of rows will ensure the same potential for the connections on the same side of the module. (In case of a plurality of rows, the total number of rows per module can be a suitable multiple of such a plurality of rows.)
(v) As a convenient approach, it was realized that the heat can be removed from the LED via the electric (e.g., copper) wiring, thereby minimizing the occupied area close to an LED.
(vi) It was realized that any wiring close to an LED might not necessarily have a circular cross section or be applied flat onto the circuit board. Instead, one can consider a flat wire disposed vertically, e.g., with its largest surface side which is placed parallel to the rays to minimize its “shadow” on the transparent circuit board/area of circuit board that is subject to light transmission along a light transmission direction that is essentially orthogonal to the plane of the circuit board.
(vii) Far away from an LED, the wiring may enlarge its area on the circuit board, in particular when it passes by the material from the reflector panel, so that it has much larger surface for an effective heat exchange. This is feasible because at the outer area, shadowing is less problematic. The heat transfer to the reflector panel may take place through a heat dissipator (portion) that is, for example, a non-electrically conductive layer on the thermal contact area. It is noted that the electric connection between the LED and the heat sink “reflector panel” can be interrupted because the heat sink may be metallic (e.g., aluminum) to be less expensive, and therefore there can be a risk of creating an electric short cut between optical cells. It was realized that-for sufficiently large surfaces (e.g., a flat area of 2 mm to 3 mm in diameter and at a corner of the, e.g., square/hexagonal shape)—a thin layer of electrically insulating material can provide sufficiently low thermal resistance (high resistivity but large area cause low resistance). For example, suitable thermal pads or aluminum nitride thin connectors can be used as interface between the electrically conducting spots and a metallic body of a reflector panel. In some embodiments, even a thin dielectric such as a thin polymeric insulating film may properly provide a desired electric insulation, due to the relatively low voltages operating the LEDs, and a desired thermal conduction.
(viii) Various configurations for electrically connecting the LEDs are proposed herein, in which the electrical conductor passes between two LEDs across a thermal contact area, optionally in an electrically insulated manner. For embodiments, in which the thermal dissipation at a corner of an optical cell is intended (as said, there is more space for the thermal contact area outside the light transmitting area at a corner of a square surface section), the electric connection of LEDs can follow a zig-zag course. For a linear course of electric connection of LEDs, passing by corners may not be feasible if the length of the wiring should be kept as short as possible. In some cases, there can be sufficient space for the thermal contact areas at the lateral sides if the optical cells (depending on the shape and extent of the concave reflecting surface area), even if the area available for shadow-free heat dissipation may be smaller at a lateral side.
(ix) Generally, the interface between the electrical connections and the reflecting panel can be filled by insulating material that provides thermal conduction. For a small gap, the filling can be based on a transparent resin, chosen with good compromise between cost and thermal conductivity.
(x) Finally, the entire well, which is formed in the reflector panel between the transparent circuit board and the reflector panel, can be filled by an insulating resin, thereby additionally minimizing reflection losses. In some alternative embodiments, the insulating resin might even be considered as a type of a transparent circuit board, carrying the LEDs instead of solid transparent circuit board, keeping in mind that the precise positioning of the LEDs should be given.

The disclosure is further based in part on the realization that heat management can already be based on an underlaying circuit configuration of the transparent circuit board (e.g., transparent PCB) when being configured for cooperating functionally with a reflector panel. Specifically, the inventors propose a basic concept for inventive topologies of spatial layouts of thermal/electrical domains of a circuit board, thereby being suitable for combination with various types of reflector panels.

On a generic point of view, a circuit board for a light emitting module comprises a plurality of mounting positions for LEDs, wherein the mounting positions are distributed in a regular two-dimensional pattern on a first surface side of the circuit board. The two-dimensional pattern defines a plurality of surface sections on the first surface side.

The surface sections have essentially the same geometry and respectively are associated with one mounting position and, thus, one LED as heat source.

With respect to an optical use/configuration of the circuit board, such as an optical configuration in which LED light is collimated and redirected through the circuit board, the circuit board can be characterized by a plurality of transparent domains, each transparent domain being a part of the respective surface section and extending around the mounting position of that respective surface section. When the circuit board is mounted to a reflector panel for its optical use, the transparent domains ensure that light, which is generated from an LED and reflected by an associated collimating portion of the reflector panel, can pass through the circuit board.

With respect to the heat management, the circuit board can be further characterized by a plurality of heat conductive domains, each heat conductive domain being a part of the respective surface section, however, located such that the heat conductive domain is outside the transparent domain. When the circuit board is mounted to a reflector panel for its optical use, the heat conductive domains enable that heat, which is generated by the LEDs during operation, can be transferred via the heat conductive domains to the reflector panel. For example, the reflector panel and the circuit board are in an areal contact at the heat conductive domains.

For efficient heat transfer, an average area of the thermally conductive domains is, for example, at least 2% such as at least 4% or at least 8% of an average area of the transparent domains.

It will be understood that the heat, which is generated by the LED, needs to flow across the transparent domain to the heat conductive domain. Enabling this flow of heat should, however, have reduced impact on the transparency of the transparent domains. Accordingly, thermal conductors connecting thermally the heat sources, i.e., the LEDs, with the heat conductive domains can be configured transparent or largely transparent or have “small” size projected onto the first surface side and block only an acceptable amount of light.

Generally, the heat conductive domains can comprise a thermally conductive material/material layer that can be transparent or even opaque because it is positioned outside the transparent domain.

The heat conductive domains can additionally be used for providing electrical power to the LEDs, in other words be a part of the LEDs' power supply circuit. In that case, a heat conductive domain can be electrically connected via an electrical and thermal conductor with a lead of the LED. Even series connections of a group of LEDs can include the heat conductive domains.

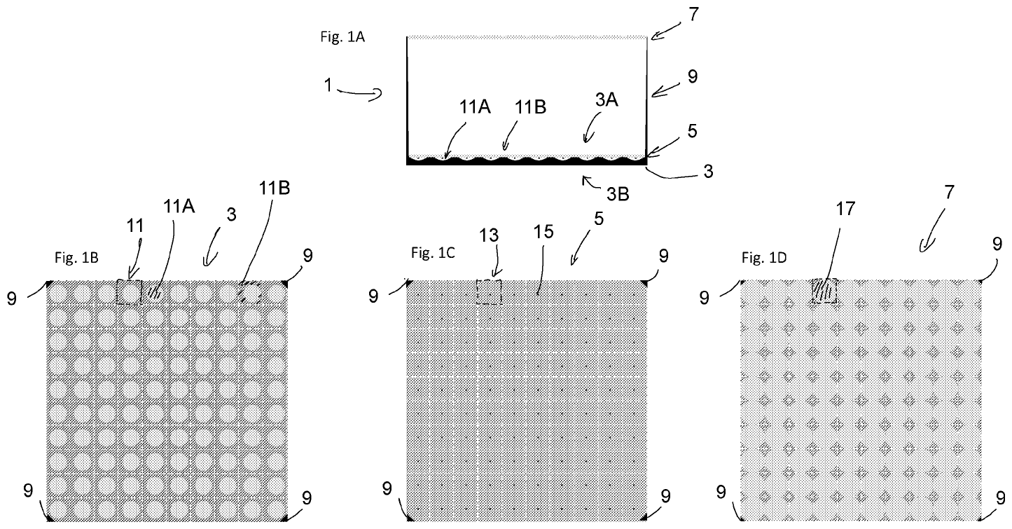

In the following, various embodiments of a light emitting module are disclosed in connection with FIGS. 1 to 14.

FIGS. 1A-1D are schematic illustrations of an exemplary light emitting module 1. Specifically, FIG. 1A is a schematic illustration of a cut view of the light emitting module 1, FIG. 1B is a schematic illustration of a top view of a reflector panel 3, FIG. 1C is a schematic illustration of a bottom view of a transparent circuit board 5, and FIG. 1D is an illustration of a lens panel 7. As shown in FIG. 1A, the components of the light emitting module 1 are mounted together by four pillars 9. As an example, the light emitting module 1 is based on a two-dimensional 10×10 array of optical cells with a square base shape, for example.

The reflector panel 3 has an inner surface side 3A (see FIG. 1A) subdivided into a two-dimensional array of square surface sections 11 corresponding to the square base shape. The square surface sections 11 are indicated by delimiting dashed lines. Each square surface section 11 comprises a concave reflecting surface area 11A and a thermal contact area 11B positioned outside of the concave reflecting surface area 11A (illustrated by dashing in two of square surface sections). The geometry of the thermal contact area 11B depends on the shape of the concave reflecting surface areas 11A. The body of the reflector panel 3 is operated as a heat sink with respect to the heat generated when operating the light emitting module 1. In particular, a bottom side 3B (see FIG. 1A) can be used for removing heat from the light emitting module 1.

In FIG. 1B, the concave reflecting surface areas 11A form a primary collimating layer and are illustrated with a circular shape, resulting in a respective surrounding shape of the thermal contact area 11B that is larger in size at the corners of each square surface section 11 than along the lateral sides of the square surface sections 11.

FIG. 1B furthermore shows in the four corners of the reflector panel 3 the pillars 9 with an exemplarily triangular cross-section, forming the corners of the light emitting module 1.

Generally, the secondary collimating layer (lens panel 7) can be suspended by suitable “poles” (pillars). A rigid configuration for a minimum pole size can be that of four poles at the four corners, e.g., with rectangular triangular base and tapered profile. The triangular section allows forming a square section when the four poles of four abutting light-emitting modules are connected. The tapered structure can facilitate extrusion and ensure a larger base at the reflector plane, where the light spot (diameter of the light beam reflected from concave reflecting surface areas) is smaller and, accordingly, there is increased room between optical “channels”. This is the case especially at the cell corners. Due to the tapering, a smaller cross-section is formed at the secondary collimating layer, at which the diameter of the light beam increased to fill the abutting lenses preferably completely such that there is a reduced space left for the poles.

FIG. 1C illustrates the separation of the transparent circuit board 5 in square surface areas 13 corresponding to the square surface sections 11. In each square surface area, an LED 15 is indicated at a central position. It is noted that FIG. 1C does not show any circuitry, which is explained later in more detail with respect to electrical and thermal conductors. As in FIG. 1B, one can recognize in the four corners the pillars 9 with the triangular cross-section.

FIG. 1C illustrates a secondary collimation layer that is formed by a respective two-dimensional array of lenses 17 that essentially fill the associated square surface section. As in FIG. 1B, one can recognize again in the four corners the pillars 9 with the triangular cross-section, that in view of the tapered base shape is reduced.

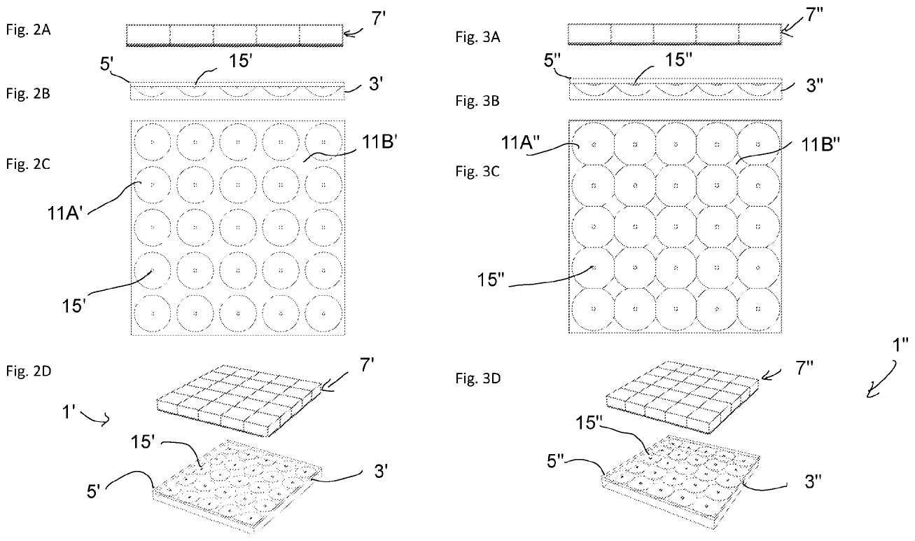

FIGS. 2A-2D and 3A-3D are schematic illustrations of further exemplary light emitting modules 1′, 1″ based on a two-dimensional 5×5 array of optical cells with a square base shape. FIGS. 2A and 3A illustrate cross-sections of secondary collimation layers 7′, 7″, respectively. FIGS. 2B and 3B illustrate schematic cross-sections through a line of LEDs 15′, 15″ for a transparent circuit board 5′, 5″ mounted to a reflector panel 3′, 3″. As can be seen, the LEDs 15′, 15″ are mounted centrally with respect to cup-shaped indents within the reflector panel 3′, 3″. As can be seen in FIG. 2B, the reflecting surface areas 11A′ transition partly from one square base shape to the next at portions along the side length of the square base shape. Thus, in FIG. 2B, the diameter of circular concave reflecting surface areas 11A′ is less than a side length of the square surface sections 11′ (shown in FIG. 2C), and an assumed diameter associated to the concave reflecting surface areas 11A″ in FIG. 3B would extend beyond the square surface sections 11″ (shown in FIG. 3C), thereby minimizing the thermal contact areas 11B″ to a star-like shape between four concave reflective surface areas 11A″ (see FIG. 3C, while FIG. 2C is similar to the appearance of the reflector panel 3 shown in FIG. 1B).

In perspective views of the light emitting modules 1′, 1″, FIGS. 2D and 3D illustrates schematically the secondary collimation layers 7′, 7″ arranged at a distance of several times the side length of the square surface sections 11′, 11″ with respect to the reflector panel 3′, 3″/transparent circuit board 5′, 5″.

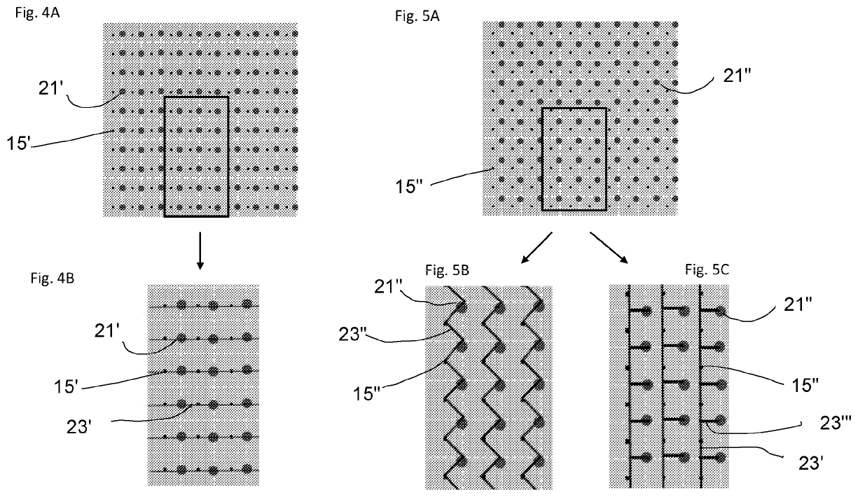

FIGS. 4 and 5 illustrate generically exemplary arrangements of the thermal contact areas with respect to the mounting positions of the LED (focus position of the reflecting surface area).

FIGS. 4A (lateral displacement with respect to LEDs and square base shape) and 5A (diagonal displacement with respect to LEDs and square base shape) illustrate possible positions for thermal contact areas 21′, 21″ on a transparent circuit board to be used with reflector panels as illustrated in FIGS. 2B and 3B, respectively. Specifically, FIG. 4A indicates one thermal contact area 21′ between pairs of LEDs 15′, thereby creating a line of alternating LEDs 15′ and thermal contact areas 21′. The thermal contact area 21′ are positioned along a side of the square surface sections, specifically to be thermally connected with thermal contact areas of the reflector panel in between a pair of neighboring concave reflecting surface areas.

FIG. 4B illustrates how a straight thermal conductor 23′ (optionally additionally used as an electrical conductor) can thermally connect a line of LEDs 15′ linearly, whereby the thermal conductor 23′ passes by a thermal contact area 21′ between two LEDs 15′. As illustrated, several linear connections of, for example equal number of, LEDs 15′ can form groups of LEDs 15′ to be provided with power in a serial connection.

Referring to FIG. 5A, thermal contact areas 21″ are provided at the corners of the square surface sections, thereby forming alternate lines of LEDs 15″ and thermal contact areas 21″. As illustrated in FIG. 5B, a thermal conductor 23″ (optionally additionally used as an electrical conductor) can thermally connect a line of LEDs 15″ along a zig-zag course. Alternatively, as shown in FIG. 5C, from a linear thermal connector 23′ extending along the lines of LEDs 15″, an additional thermal connector segment 23″' can thermally connect the linear thermal connector 23′ between LEDs 15″ with the thermal contact areas 21″.

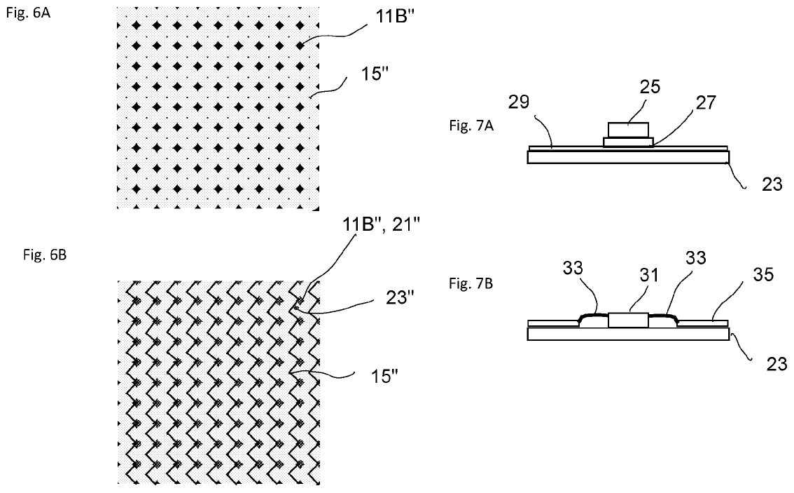

The following description with respect to FIGS. 6-12 illustrate exemplary configurations of thermal and/or electrical contacts between mounting positions of the LED and the thermal contact areas.

FIGS. 6A and 6B illustrate an implementation of the thermal connection in zig-zag course on the circuit board for a reflector panel as shown in FIG. 3B. FIG. 6A shows star-shaped thermal contact areas 11B″ on the corners of the square surface sections (these “rhomboids” being “flat tips” of the surface of the reflector panel) as well LEDs 15″ centered with respect to the star-shaped thermal contact areas 11B″. One can see how the thermal contact areas 21″ of the circuit board (dots in FIG. 6B) are positioned on the star-shaped thermal contact areas 11B″. Thus, the thermal conductor 23″ thermally connects each of the thermal contact areas 21″ (and accordingly also each of the star-shaped thermal contact areas 11B″) with two LEDs 15″, which is made possible by its zig-zag course.

FIGS. 7A and 7B illustrate how LEDs may be mounted to a support board 23 of the transparent circuit board at respective mounting positions. FIG. 7A illustrates an LED 25 having its heat sink 27 attached via a heat conductor, in this case a heat conductive layer 29, at the support board 23. A large area thermal contact between the heatsink 27 and the heat conductive layer 29 allows removing the heat generated by the LED 25 during operation and transmitting the heat via the heat conductive layer 29 to a thermal contact to the reflector panel (not shown). As will be shown in the following examples, the heat conductive layer 29 may be configured as a heat conductor (thin in laterally dimensions to block as less light as possible) or a light transparent spread-out layer, which can be based, for example, on an ITO (indium tin oxide) layer. It is noted that in FIG. 7A electrical connections are not shown, which are usually insulated from the heat conductive layer 29.

FIG. 7B illustrates an embodiment, which uses the electrical circuit additionally for removing heat. Specifically, an LED 31 is mounted to the support board 23 at its respective mounting position. Leads 33 of the LED 31 are connected to electrical conductors 35 in a manner that heat generated by the LED 31 during operation can be extracted and transferred to the electrical conductors 35 and further guided to thermal contact with the reflector panel. It will be understood that a respective electrical insulation may be needed between the electrical conductors 37 and the reflector panel (usually at ground potential).

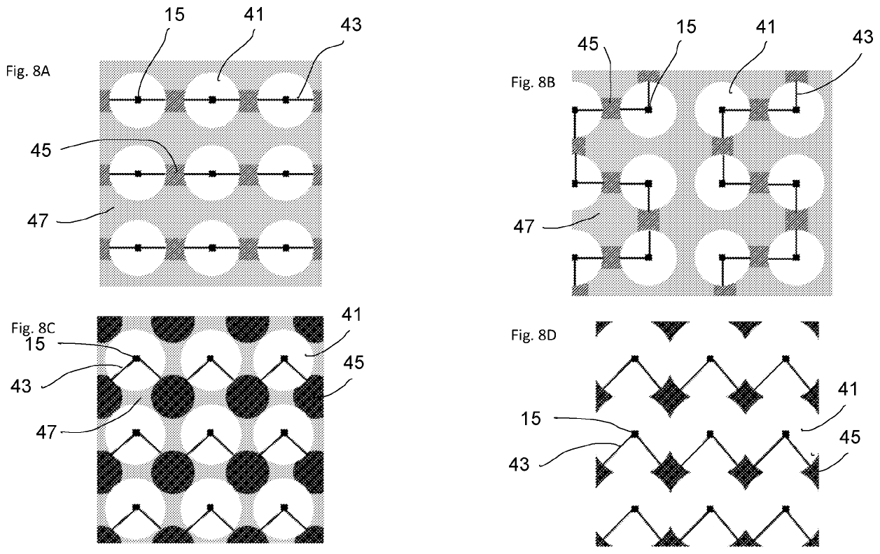

FIGS. 8A-8D illustrate various exemplary configurations of the circuit provided on the circuit board for thermal and optionally electrical contacting every LED 15. In the schematically bottom views, one recognizes circularly shaped light transmitting regions 41 surrounding the LEDs 15, and heat conductors 43 linearly extending through the light transmitting regions 41. The heat conductors 43 originate at the LEDs 15 and extend in a radial direction to ensure a minimal light blocking extent. The conductors 43 are connected to thermal contact areas 45. The thermal contact areas 45 extend as a two-dimensional area to provide a significant surface area for contacting the reflector panel. It will be acknowledged that the shown configurations can be used either only for heat removal, then additional electrical contacts need to be provided to the LEDs 15, or the heat conductors 43 are in addition used for electrically supplying power to the LEDs 15. For illustration purposes, the light transmitting regions 41 are indicated in white in the drawings, thereby distinguished from the thermal contact areas 45 (indicated by a pattern) as well as the remaining area 47 (indicated by a gray coloring). The remaining area 47 may be uncoated or, for example, be specifically used for implementing any additional power supplying electric circuit for the LEDs 15. It is further noted that the underlying reflector panel needs to provide respective counterpart thermal contact areas that can ensure proper thermal contact to the thermal contact areas 45 of the circuit board.

Returning specifically to FIG. 8A, one recognizes a linear thermal (and optionally electrical) connection of three LEDs 15 forming three rows of LEDs. FIG. 8B connects two rows of LEDs 15 within one thermal (and optionally electrical) connection. FIGS. 8C and 8D relate to configurations where the thermal contact areas 45 are displaced from the linear arrangement of LEDs such that a zig-zag course of the thermal (and optionally electrical) connection is implemented. While the configuration of FIG. 8C relates to an embodiment, where the light transmitting regions 41 are in diameter smaller than the side length of the square surface sections, FIG. 8B relates to an embodiment, where the light transmitting regions 41 are in diameter slightly larger than the side length of the square surface sections, resulting in the star-shaped thermal contact areas 45 (see also FIGS. 6A and 6B).

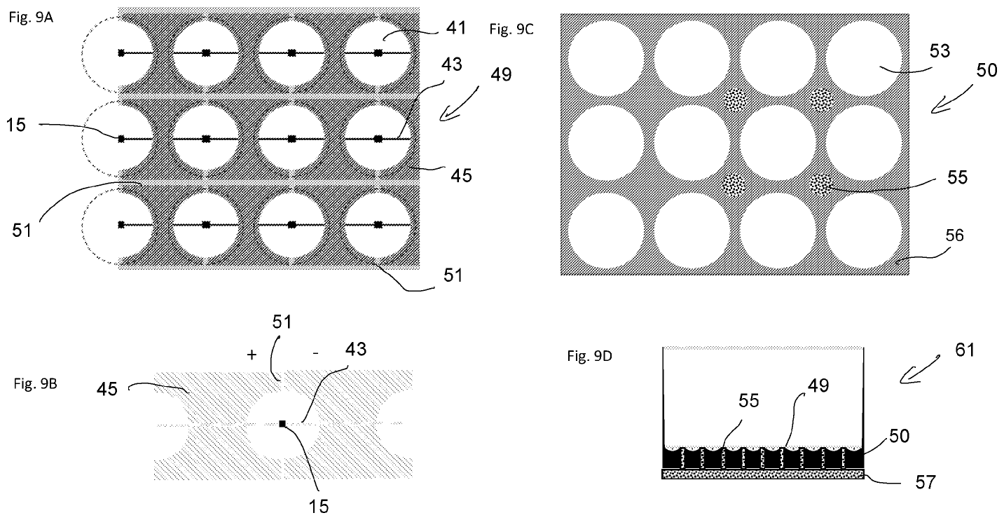

FIG. 9 illustrates electrical contacting of LEDs 15 (FIGS. 9A and 9B) provided on a circuit board 49 and an approach for increased thermal removal of heat through a reflector panel 50, the latter approach being also usable for a precise mounting of the reflector panel 50.

Similar to FIG. 8A, LEDs within light transmitting regions 41 of the circuit board 49 are connected in line via heat conductors 43 and thermal contact areas 45 that are also used for power supply. It is noted that the thermal contact areas are made as large as possible. To separate different potentials of the thermal contact areas 45, FIG. 9B shows remaining uncoated lines 51. The shaded areas of FIG. 9B may be conductive, such that any short circuit should be avoided. The transparent areas of the circuit board, such as the light transmitting regions 41, are essentially electrically insulating. If the thermal contact areas 45 are used for power supply, neighboring thermal contact areas 45 are electrically connected only through the LED 15, which is surrounded by the insulating light transmitting region 41.

In case of using the circuit board 49 with an electrically conductive reflector panel, a thin insulating layer can be implemented, for example, to cover the circuit. In another embodiment, an electrically insulating reflector panel can have, e.g., areas of a metallic coating for forming the concave reflecting surface areas. As further discussed herein, materials used for the reflector panel, the circuit board as well as the secondary collimation layer can be specifically selected with respect to thermal expansion, for example, and alignment stability, environments for use/transport etc.

Moreover, FIG. 9A indicates circular reflecting surface areas of an associated reflector panel (dashed circles). FIG. 9B illustrates the electrical circuit comprising the large area thermal/electrical contact areas 45, the heat conductors 43, and an LED 15. “+” and “−” indicate the function as anode and cathode with respect to the LED 15.

FIG. 9C is a top view of the exemplary reflector panel 50 with circularly reflecting surface areas 53 (in white, for example, metal coated) for being used, for example, with the circuit board of FIG. 9A that is thermally in contact with the reflector panel 50 at the surrounding thermal contact (surface) area 56. As an exemplary additional feature, FIG. 9C illustrates metallic inserts 55 (exemplarily illustrated only at four corners of the square surface sections) to increase the thermal conductivity of the reflector panel 50. It will be acknowledged that an electrical insulation either on the reflector panel 50 or the circuit board will be required.

FIG. 9D illustrates how the metallic inserts 55 can be used to mount the reflector panel within a light emitting module 61. In this case, the metallic inserts 55 extends from a metallic bottom 57 acting as a heatsink of the light emitting module 61 at predefined positions to ensure proper alignment of the reflector panel 50/the light emitting module 61.

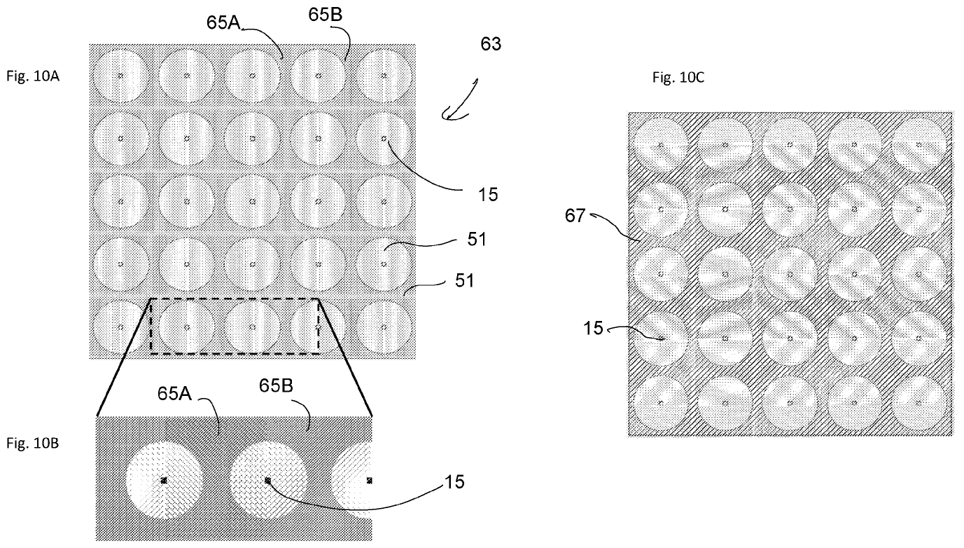

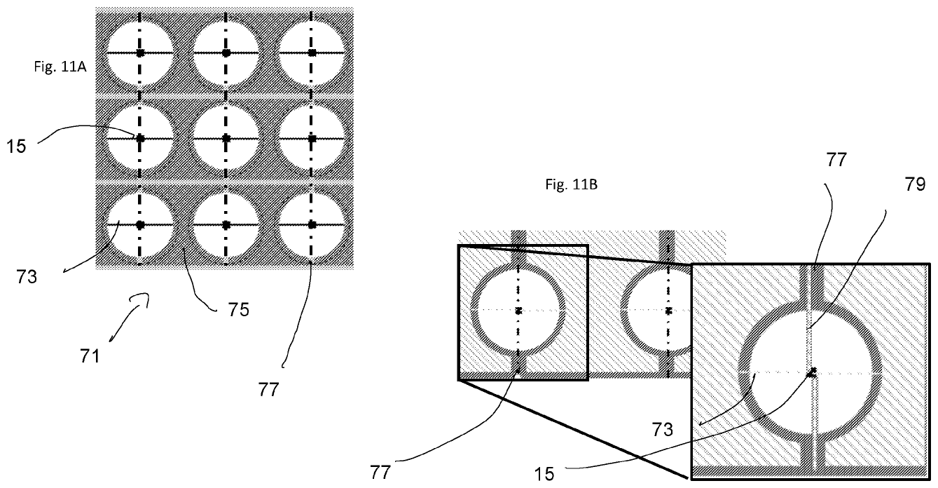

FIG. 10 illustrates a circuit board 63 using an ITO layer for electrically connecting LEDs 15. As can be seen in particular in the enlarged portion of FIG. 10B, alternating sections 65A, 65B of the ITO layer electrically contact the LEDs, and accordingly are electrically insulated with respect to each other via uncoated lines 51. Neighboring ITO layers are connected only through the LED. The ITO layers are optically transparent and enable additionally distributing heat generated by the LEDs 15 over a large area such that the same can be removed via a thermally connected reflector panel.

With respect to electrically insulating the circuit board 63 from the thermally connected reflector panel, FIG. 10C shows a thin dielectric insulating layer 67 outside of the light transmitting regions of the circuit board 63 that is applied on top of the thermal contact areas, here the ITO layer.

FIG. 11 illustrates a combination of thermal conductors and electrical conductors in a configuration of a circuit board 71 similar to the one of FIG. 9A. As in FIG. 9A, thermal connection of LEDs 15 is achieved laterally using heat conductors 73 and thermal contact areas 75. In addition, electrical connection is achieved orthogonal to the heat connection (dashed dotted lines in FIG. 11A extending along non-coated areas 77 of the circuit board 71 from light transmitting area to light transmitting area). Exemplary electrical conductors 79 are explicitly shown in the enlargement of FIG. 11B. For example, the thermal connectors (heat conductors 73) are configured to receive heat from a heatsink of the LED 15 (see discussion in connection with FIG. 7A) and the electrical conductors 79 are connected with leads of the LED for power supply.

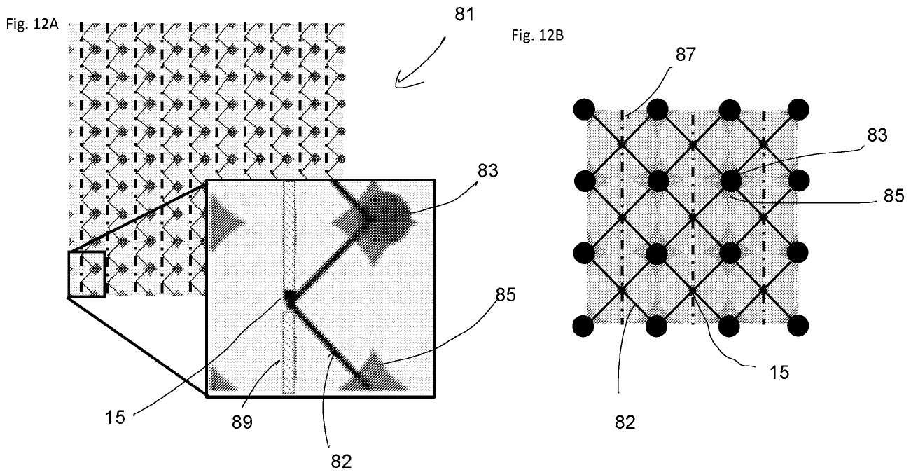

FIG. 12 illustrates further combinations of thermal conductors and electrical conductors in a configuration of a circuit board 81 similar to the one of FIG. 6A.

In the embodiment of FIG. 12A, it is shown a zig-zag course of thermal connections 82 of the LEDs 15 with thermal contact areas 83 of the circuit board and star-shaped thermal contact areas 85 on the corners of the square surface sections of the reflector panel (not shown). In addition, the LEDs 15 are electrically connected linearly through the light transmitting areas (illustrated by dashed dotted lines 87 in FIG. 12A and the electrical connector 89 in the magnified portion).

In the embodiment of FIG. 12B, four thermal contact areas 83 of the circuit board are connected with a heatsink of the LED 15 in a cross-like arrangement of heat conductors (thermal connections 82), while the power supply again is achieved along a linear electrical connection (dashed dotted lines 87 in FIG. 12B).

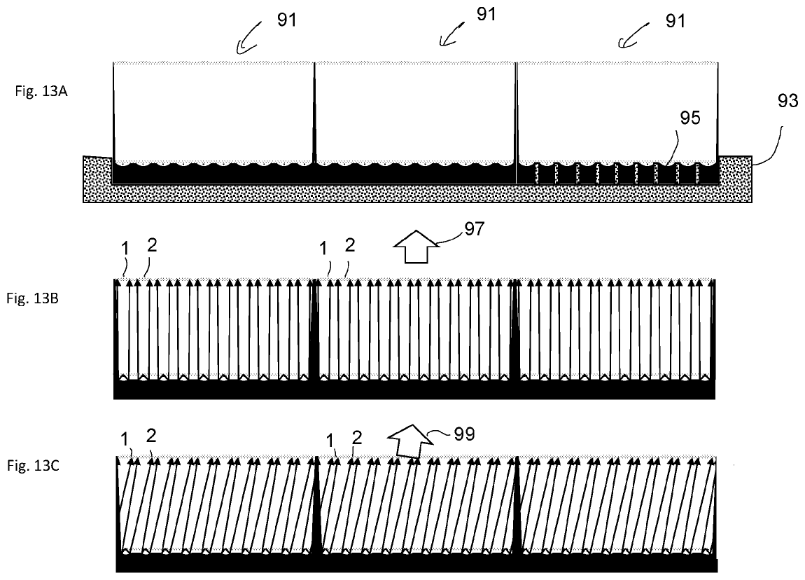

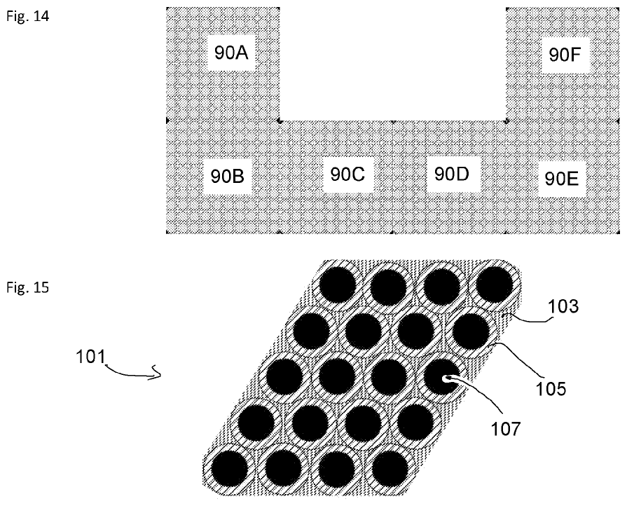

The light-emitting modules disclosed herein can be combined to provide larger emitting surface of directed light in a modular device. For example, FIG. 13A shows schematically arrangement of three light-emitting modules 91 and FIG. 14 shows an arrangement of six reflector panels 90A-90F arranged in a, for example, U-shape.

Referring to the embodiment shown in FIG. 13A, a frame 93 keeps the plurality of light-emitting modules 91 precisely positioned with respect to each other.

As mentioned in context with FIG. 9D, heat conducting inserts 95 can reach through the reflector panel towards the circuit board and, thereby, improve the heat removal from the transparent board through the reflector panel to the bottom side. In the embodiment of FIG. 13A the conducting inserts 95 are connected to (or part of) the frame 93. The inserts 95 may further improve the mounting position of the light-emitting modules 91 onto the frame 93 and in particular with respect to each other.

FIG. 13B (modular device with orthogonal light emission) illustrates that for a retro-reflecting configuration of the reflector panel, light rays reflected by one of the concave reflecting surface area pass through a single lens of the second collimation layer, wherein that lens is associated with the same (square or hexagonal, for example) surface section. Accordingly, the output light 97 will be directed orthogonally with respect to the reflector panel.

Alternatively, as shown in FIG. 13C (modular device with inclined light emission), light rays reflected by one of the concave reflecting surface area can pass through a single lens of the second collimation layer, wherein that lens is associated with another one of the (square or hexagonal, for example) surface section. In the example of FIG. 13C, the light rays pass through the lens of the neighboring surface section. One recognizes that inclination angles of the output light 99 depend on the position of the “passed through lens” and a distance between the primary collimation layer (e.g., reflector panel) and the secondary collimation layer (e.g., lens panel). The inclination can, for example, be achieved by a mounting position of an LED laterally displaced with respect to a mounting position for orthogonal light emission. It is noted that a plurality of respective LED arrays may be provided together on one circuit board to allow for a change in the light emission direction by switching the operation between different LED arrays (or providing multiple light beams in different directions by operating multiple LED arrays at once). The shift between the LED arrays depends on the pitch of the optical cells and/or on the distance to the secondary collimator layer. An alternative configuration may be based on a specifically designed geometry such as a tilted reflecting surface, here tilted with respect to an orientation of a geometry for orthogonal light emission area. It will be understood that the modular approach imposes a constraint on the tilt angle when will it is intended to have the output light emitted at some angle. As explained, the angles cannot be selected arbitrary but instead can be chosen among a discrete set of tilt angles that allow an LED from one optical cell to illuminate a collimating lens from a neighboring optical cell (1st tilt angle) or from another further away optical cell. It is noted that with respect to optical cells at the border of the light-emitting module, LEDs from one light-emitting module will illuminate collimating lenses from another light-emitting module.

Specifically, with respect to the modular approach a suitable approach for the LED electric wiring can be set up that prevents having close contact points with different potential. Specifically, a series LED connection may allow the same current and, thus, the same light emission from each LED and improves a desired uniformity across the output aperture of the light-emitting module. Additionally, the series may also produce individually the same light emission as the random resistance fluctuation of different LEDs produces a smaller impact the larger the number of LEDs is. In some embodiments, abutting light-emitting modules have the same electric potential at the connecting side. For example, at one connecting side, a ground potential is provided for two light-emitting modules left and right of that connecting side, while the respective other sides are kept at operating potential.

FIG. 15 is a schematic top view illustration of a light-emitting module 101 that is based on an arrangement of hexagonal optical cells. The optical cells are implemented in a reflector panel and a transparent board, respectively. The hexagonal shape of the optical cells can be seen at the four corners and the resulting parallelogram-like base shape of the light-emitting module 101. Specifically, heat conducting areas 103 are illustrated by vertical lines, circular reflecting surface areas 105 of the reflector panel are indicated in black, and transparent areas 107 within the transparent board extend at least over the areas comprising the circular reflecting surface areas 105 in black and the surrounding rings indicated in diagonal lines (larger than the circular reflecting surface areas 105 in view of a divergence of a reflected light beam and or tilted output direction).

Although the preferred embodiments of this invention have been described herein, improvements and modifications may be incorporated without departing from the scope of the following claims.

1. A circuit board for a light emitting module, the circuit board comprising:
a plurality of mounting positions for LEDs, wherein the mounting positions are distributed in a regular two-dimensional pattern on a first surface side of the circuit board; and wherein
the circuit board is characterized by
(i) a plurality of transparent domains, each transparent domain extending around one mounting position of the plurality of mounting positions, and
(ii) a plurality of thermally conductive domains, each thermally conductive domain being thermally and electrically connected to at least one mounting position,
wherein an average area of the thermally conductive domains is at least 2% or at least 4% or at least 8% of an average area of the transparent domains, and
wherein each thermally conductive domain of the plurality of thermally conductive domains comprises at least a portion which extends as a two-dimensional area on a surface of the circuit board.

2. The circuit board of claim 1, wherein the thermally conductive domains, in particular a material layer forming the thermally conductive domains, have an electrical resistivity in Ω·m that is 10¹⁰, preferably 10¹⁵, even more preferably 10¹⁸ times smaller than an electrical resistivity of the transparent domains, in particular a material layer forming the transparent domains between a mounting position and a thermally conductive domain.

3. The circuit board of claim 1 or 2, wherein the thermally conductive domains are at least partially covered by an electrically insulating layer.

4. The circuit board of any one of claims 1 to 3, wherein the thermally conductive domains comprise thermal connectors that extend across the transparent domains.

5. The circuit board of claim 4, wherein the thermal connectors are at least one of
made of an opaque material, in particular an opaque material layer,
made of an ITO material, and
configured as substantially flat connectors that are oriented with the larger surface inclined, in particular orthogonal, to the first surface side of the support board.

6. The circuit board of any one of the preceding claims, wherein the thermally conductive domains cover at least 90% of an area of the circuit board that is not associated with the transparent domains.

7. The circuit board of any one of preceding claims, wherein the transparent domains have a transparency of 75% and more, such as of 85% and more or of 95% and more, preferably even a transparency larger than 98%, with respect to visible light.

8. The circuit board of any one of preceding claims, wherein the transparent domains have a transparency that is at least 10 times larger than a transparency of the electrically conductive domains.

9. The circuit board of any one of preceding claims, further comprising a plurality of LEDs mounted respectively to the support board at the plurality of mounting positions and configured to emit light into the hemisphere delimited by the first surface side.

10. The circuit board of claim 9,
wherein each LED of the plurality of LEDs has a heat sink that is positioned in a central region of a respective transparent domain of the plurality of transparent domains; and
wherein the plurality of thermally conductive domains comprises a thermally conductive layer and thermal connections respectively connecting one of the heat sinks with the thermally conductive layer in one of the thermally conductive domains.

11. The circuit board of any one of preceding claims, wherein the thermally conductive domains comprise a plurality of areal electrical connecting sections which define heat removing regions of the support board.

12. The circuit board of claim 11,
wherein the areal electrical connecting sections extend outside the transparent domains, and
wherein the thermally conductive domains also comprise a plurality of linear electrical connecting sections extending across the transparent domains to electrically and thermally connect the LEDs with the areal electrical connecting sections.

13. The circuit board of claim 12,
wherein the linear electrical connecting sections have a first thickness in a dimension orthogonal to the surface of the circuit board and the areal electrical connecting sections have a second thickness in a dimension orthogonal to the surface of the circuit board, with the first thickness being larger than the second thickness, such as 1.5 times larger, 2 times larger or 4 times larger.

14. A light emitting module comprising:
a reflector panel having an inner surface side subdivided into a two-dimensional array of surface sections, such as surface sections having a square or hexagonal geometry, generally a geometry that allows combination to cover a continuous surface, wherein each surface section comprises a concave reflecting surface area and a thermal contact area outside of the concave reflecting surface area;
a transparent circuit board mounted to the reflector panel with a first surface side facing the inner surface side of the reflector panel;
LEDs distributed in a two-dimensional array on the first surface side of the transparent circuit board such that each LED is associated with one of the concave reflecting surface areas;
heat conductors that respectively thermally connect one of the LEDs with one of the thermal contact areas;
wherein in particular, during operation of the light emitting module,
light emitted from one of the LEDs is reflected by the associated concave reflecting surface area to pass through the transparent circuit board, and
heat generated by the LEDs is spread via the heat conductors and the thermal contact areas.

15. The light emitting module of claim 14, further comprising
a lens arrangement mounted at a distance of at least 3 times of a side length of the surface section from the transparent circuit board, and preferably comprising a plurality of abutting lenses respectively associated with one of the surface sections.

16. The light emitting module of claim 14 or 15,
wherein, during operation, light emitted from one of the LEDs is reflected by the associated one of the concave reflecting surface areas to pass through the transparent circuit board, and collimated by one of the lenses of the lens arrangement.

17. An LED-based optical system/light emitting module comprising:
a support board with a plurality of mounting positions, wherein
the mounting positions are distributed in a regular two-dimensional pattern on a first surface side of the support board, and
the support board is transparent with respect to visible light at least within a plurality of transmission areas (light transmitting regions), each transmission area extending around one of the plurality of mounting positions, and
wherein the regular two-dimensional pattern is defined by equal distances between neighboring mounting positions in a respective direction;
a plurality of light sources mounted to the support board at the plurality of mounting positions, wherein each light source includes at least one LED,
a reflector panel having a three-dimensionally shaped surface and mounted to the support board, wherein
the three-dimensionally shaped surface faces the first surface side of the support board and includes a plurality of connecting surface sections (thermal contact areas) and a plurality of reflective surface sections (concave reflecting surface areas),
the plurality of connecting surface sections extends within a connecting plane and is in contact with the first surface side of the support board, and
each reflective surface section faces an associated transmission area of the support board; and
a plurality of conducting tracks (heat conductors) extending on the first surface side and configured for thermal dissipation of heat from the light source and/or for power supply of the light source, wherein at least one of the plurality of conducting tracks extends from one of the plurality of mounting positions to at least one of the plurality of connecting surface sections.
